(19) United States
(12) Patent Application Publication
(10) Pub. No.: US 2012/0090486 A1
(43) Pub. Date: Apr. 19, 2012

(54) LITHOGRAPHIC PRINTING PLATE PRECURSORS AND METHODS OF USE

(76) Inventor: Celin Savariar-Hauck, Badenhausen (DE)

(21) Appl. No.: 12/906,228

(22) Filed: Oct. 18, 2010

(51) Int. Cl. B41N 1/00; G03F 7/26; G03F 7/004

(52) U.S. Cl. 101/453; 430/270.1; 430/278.1; 430/302

(57) ABSTRACT

Negative-working, infrared radiation-sensitive lithographic printing plate precursors have an imageable layer on a substrate. The imageable layer includes a free radically polymerizable component, an initiator composition capable of generating free radicals upon exposure to infrared radiation, a polymeric binder, one or more infrared radiation absorbing compounds, and an inorganic phosphoric acid or inorganic phosphoric acid precursor. The lithographic printing plate precursors can be designed for either off-press or on-press development after IR imaging.

### FIELD OF THE INVENTION

This invention relates to lithographic printing plate precursors that exhibit improved shelf life. These lithographic printing plate precursors are negative-working elements. This invention also relates to a method of imaging and developing such lithographic printing plate precursors either on-press or off-press.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink the ink receptive regions accept the ink and repel the water. The ink is then transferred to the surface of suitable materials upon which the image is to be reproduced. In some instances, the ink can be first transferred to an intermediate blanket that in turn is used to transfer the ink to the surface of the materials upon which the image is to be reproduced.

Lithographic printing plate precursors useful to prepare lithographic (or offset) printing plates typically comprise one or more imageable layers applied over a hydrophilic surface of a substrate (or intermediate layers). The imageable layer(s) can comprise one or more radiation-sensitive components dispersed within a suitable binder. Following imaging, either the exposed regions or the non-exposed regions of the imageable layer(s) are removed by a suitable developer, revealing the underlying hydrophilic surface of the substrate. If the exposed regions are removed, the element is considered as positive-working. Conversely, if the non-exposed regions are removed, the element is considered as negative-working. In each instance, the regions of the imageable layer(s) that remain are ink-receptive, and the regions of the hydrophilic surface revealed by the developing process accept water or aqueous solutions (typically a fountain solution), and repel ink.

“Laser direct imaging” methods (LDI) have been known that directly form an offset printing plate or printing circuit board using digital data from a computer, and provide numerous advantages over the previous processes using masking photographic films. There has been considerable development in this field from more efficient lasers, improved imageable compositions and components thereof.

Various radiation-sensitive compositions are known for use in negative-working lithographic printing plate precursors as described for example in U.S. Pat. Nos. 6,309,792 (Hauck et al.), 6,893,797 (Munnelly et al.), 6,727,281 (Tao et al.), 6,899,994 (Huang et al.), and 7,429,445 (Munnelly et al.), U.S. Patent Application Publications 2002/0168494 (Nagata et al.), 2003/0118939 (West et al.), and EP Publications 1,079,276A2 (Lifka et al.) and 1,449,650A2 (Goto et al.).

U.S. Pat. No. 7,429,445 (Munnelly et al.) describes on-press developable negative-working lithographic printing plate precursors that contain various infrared radiation absorbing dyes that have tetraaryl pentadiene chromophores, and nonionic phosphate acrylates to increase imaging sensitivity.

Various negative-working imageable elements have been designed for processing or development “on-press” using a fountain solution, lithographic printing ink, or both. For example, such elements are described in U.S. Patent Application Publication 2005-263021 (Mitsumoto et al.) and in U.S. Pat. Nos. 6,071,675 (Teng), 6,387,595 (Teng), 6,482,571 (Teng), 6,495,310 (Teng), 6,541,183 (Teng), 6,548,222 (Teng), 6,576,401 (Teng), 6,899,994 (Huang et al.), 6,902,866 (Teng), and 7,089,856 (Teng).

Whether the lithographic printing plate precursors are designed for on-press or off-press development after infrared radiation imaging, they generally comprise an aluminum-containing substrate. Such substrates are commonly anodized with sulfuric acid or phosphoric acid, or a mixture of both acids, to prepare an aluminum oxide film on the substrate that improves its hydrophilicity and repellency to ink during printing as well as adhesion to the overlying imageable layer.

Organic phosphonic acids have been used added to photosensitive layers to improve developability as described in EP 2,042,924 (Fujii et al.). Other lithographic printing plate precursors contain polymeric binders containing phosphoric acid groups, for example, as described in U.S. Patent Application Publication 2007/072116 (Yamasaki et al.) and U.S. Pat. No. 5,320,928 (Aoai), or some contain IR dyes having phosphoric acid functional groups as described in WO 2007/071552 (Verdonck et al.).

However, despite the continued progress in making useful negative-working lithographic printing plate precursors that have sulfuric acid-anodized aluminum substrates, there is a need to improve the shelf life and wearability during longer print runs so that toning is reduced in the printed impressions. Toning is evident with unwanted ink in the background regions. This problem has been particularly observed with lithographic printing plate precursors that are designed to be developed on-press using a fountain solution, lithographic printing ink, or both fountain solution and printing ink.

### SUMMARY OF THE INVENTION

To address the problem noted above, this invention provides a negative-working, infrared radiation-sensitive lithographic printing plate precursor comprising a substrate and having thereon an imageable layer comprising:

a free radically polymerizable component,

an initiator composition capable of generating free radicals upon exposure to infrared radiation,

a polymeric binder,

one or more infrared radiation absorbing compounds, and

an inorganic phosphoric acid or inorganic phosphoric acid precursor in an amount of at least 0.1 weight % of the imageable layer total solids.

This invention also provides a method of making a lithographic printing plate comprising:

A) imagewise exposing the negative-working, infrared radiation-sensitive lithographic printing plate precursor of this invention to imaging infrared radiation to produce exposed and non-exposed regions in the imageable layer, and

B) developing the imagewise exposed precursor to remove the non-exposed regions of the imageable layer.

In many embodiments, the developing is advantageously carried out on-press using a fountain solution, lithographic printing ink, or a combination thereof. But, in other embodiments, developing is carried out off-press using an aqueous developer (described below).

This invention provides a lithographic printing plate that can be obtained from the method of this invention, that is, the resulting imaged and developed lithographic printing plate contains some residual inorganic phosphoric acid or inorganic phosphoric acid precursor in the imaged regions remaining on its printing surface.

I have found that the present invention provides an advantageous way to improve shelf life and to reduce the occurrence of toning in printed images that is reducing unwanted background density. These advantages are achieved by incorporating an inorganic phosphoric acid (or inorganic phosphoric acid precursor), as described below, into the imageable layer of negative-working lithographic printing plate precursors in an amount of at least 0.1 weight % based on the imageable layer total solids.

### DETAILED DESCRIPTION OF THE INVENTION

### Definitions

Unless the context indicates otherwise, when used herein, the terms “negative-working lithographic printing plate precursor”, “lithographic printing plate precursor”, “printing plate precursor”, and “precursor” are meant to be references to embodiments of the present invention.

In addition, unless the context indicates otherwise, the various components described herein such as “infrared absorbing compound”, “first infrared radiation absorbing compound”, “second infrared radiation absorbing compound”, “initiator”, “co-initiator”, “free radically polymerizable component”, “polymeric binder”, and similar terms also refer to mixtures of such components. Thus, the use of the articles “a”, “an”, and “the” is not necessarily meant to refer to only a single component.

Moreover, unless otherwise indicated, percentages refer to percents by total dry weight, for example, weight % based on total solids of either an imageable layer or radiation-sensitive composition. Unless otherwise indicated, the percentages can be the same for either the dry imageable layer or the total solids of radiation-sensitive composition.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

As used herein, a “stack” of lithographic printing plate precursors includes multiple precursors. Interleaf paper can be present between adjacent precursors, or it can be absent from the stack. Generally, a stack has at least 2 and more typically at least 10 and up to and including 1500 lithographic printing plate precursors, or at least 100 of them, or at least 250 and up to and including 1000 of the precursors.

### Substrates

The substrate used to prepare the lithographic printing plate precursors of this invention comprises a support that can be composed of any material that is conventionally used to prepare lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metalized papers), or a lamination of any of these materials (such as a lamination of an aluminum foil onto a polyester film). Metal supports include sheets or foils of aluminum, copper, zinc, titanium, and alloys thereof.

One useful substrate is an aluminum-containing support that can be treated using techniques known in the art, including roughening of some type by physical (mechanical) graining, electrochemical graining, or chemical graining, usually followed by acid anodizing. The aluminum-containing support can be roughened by physical or electrochemical graining and then anodized using phosphoric or sulfuric acid (or a mixture of both phosphoric and sulfuric acids) and conventional procedures. A useful hydrophilic lithographic substrate is an electrochemically grained and sulfuric acid-anodized aluminum-containing substrate that provides a hydrophilic surface for lithographic printing.

Sulfuric acid anodization of the aluminum support generally provides an oxide weight (coverage) on the surface of at least 1.5 and up to and including 5 g/m², and can provide longer press life. Phosphoric acid anodization generally provides an oxide weight on the surface of at least 1 and up to and including 5 g/m².

The aluminum-containing substrate can also be post-treated with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or an acrylic acid copolymer to increase hydrophilicity. Still further, the aluminum-containing substrate can be treated with a phosphate solution that can further contain an inorganic fluoride (PF). It is particularly useful to post-treat the sulfuric acid-anodized aluminum-containing substrate with either poly(acrylic acid) or poly(vinyl phosphonic acid).

The thickness of the substrate can be varied but should be sufficient to sustain the wear from printing and thin enough to wrap around a printing form. Useful embodiments include a treated aluminum foil having a thickness of at least 100 μm and up to and including 700 μm.

### Negative-Working Lithographic Printing Plate Precursors

The precursors are negative-working, and can be formed by suitable application of a radiation-sensitive composition as described below to a suitable substrate (described above) to form an imageable layer. There is generally only a single imageable layer comprising the radiation-sensitive composition and it is the outermost layer in the element. For the on-press developable lithographic printing plate precursors, no oxygen barrier or topcoat is generally present in the lithographic printing plate precursors. However, such a topcoat can be present over the imageable layers designed for off-press development.

Negative-working lithographic printing plate precursors are described for example, in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. Nos. 4,511,645 (Koike et al.), 6,027,857 (Teng), 6,309,792 (Hauck et al.), 6,569,603 (Furukawa et al.), 6,899,994 (Huang et al.), 7,045,271 (Tao et al.), 7,049,046 (Tao et al.), 7,261,998 (Hayashi et al.), 7,279,255 (Tao et al.), 7,285,372 (Baumann et al.), 7,291,438 (Sakurai et al.), 7,326,521 (Tao et al.), 7,332,253 (Tao et al.), 7,442,486 (Baumann et al.), 7,452,638 (Yu et al.), 7,524,614 (Tao et al.), 7,560,221 (Timpe et al.), 7,574,959 (Baumann et al.), 7,615,323 (Shrehmel et al.), and 7,672,241 (Munnelly et al.), and U.S. Patent Application Publications 2003/0064318 (Huang et al.), 2004/0265736 (Aoshima et al.), 2005/0266349 (Van Damme et al.), and 2006/0019200 (Vermeersch et al.), all of which are incorporated herein by reference. Other negative-working compositions and elements are described for example in U.S. Pat. Nos. 6,232,038 (Takasaki), 6,627,380 (Saito et al.), 6,514,657 (Sakurai et al.), 6,808,857 (Miyamoto et al.), and U.S. Patent Publication 2009/0092923 (Hayashi), all of which are incorporated herein by reference.

The radiation-sensitive compositions and imageable layers used in such precursors can generally include one or more polymeric binders that facilitate the on-press developability of the imaged precursors. Such polymeric binders include but are not limited to, those that are not generally crosslinkable and are usually present at least partially as discrete particles (not-agglomerated). Such polymers can be present as discrete particles having an average particle size of at least 10 and up to and including 500 nm, and typically at least 100 and up to and including 450 nm, and that are generally distributed uniformly within that layer. The particulate polymeric binders exist at room temperature as discrete particles, for example in an aqueous dispersion. Such polymeric binders generally have a molecular weight (Mₙ) of at least 5,000 and typically at least 20,000 and up to and including 100,000, or at least 30,000 and up to and including 80,000, as determined by Gel Permeation Chromatography.

Useful particulate polymeric binders generally include polymeric emulsions or dispersions of polymers having hydrophobic backbones to which are directly or indirectly linked pendant poly(alkylene oxide) side chains (for example at least 10 alkylene glycol units), cyano side chains, or both types of side chains, that are described for example in U.S. Pat. Nos. 6,582,882 (Pappas et al.), 6,899,994 (Huang et al.), 7,005,234 (Hoshi et al.), and 7,368,215 (Munnelly et al.) and US Patent Application Publication 2005/0003285 (Hayashi et al.), all of which are incorporated herein by reference. More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, in recurring units arranged in random fashion to form the polymer backbone, and various hydrophilic polymeric binders that can have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

Alternatively, the particulate polymeric binders can also have a backbone comprising multiple (at least two) urethane moieties. Such polymeric binders generally have a molecular weight (Mₙ) of at least 2,000 and typically at least 100,000 and up to and including 500,000, or at least 100,000 and up to and including 300,000, as determined by dynamic light scattering.

Additional useful polymeric binders are particulate poly(urethane-acrylic) hybrids that are distributed (usually uniformly) throughout the imageable layer. Each of these hybrids has a molecular weight of at least 50,000 and up to and including 500,000 and the particles have an average particle size of at least 10 and up to and including 10,000 nm (typically at least 30 and up to and including 500 nm or at least 30 and up to and including 150 nm). These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that can also include commercial surfactants, anti-foaming agents, dispersing agents, anti-corrosive agents, and optionally pigments and water-miscible organic solvents.

These polymeric binders are generally present in an amount of at least 5 and up to and including 70 weight % of the radiation-sensitive composition.

The radiation-sensitive composition can include a secondary polymeric binder that can be homogenous, that is, non-particulate or dissolved in the coating solvent, or they can exist as discrete particles. Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. Nos. 6,309,792 (Hauck et al.), 6,352,812 (Shimazu et al.), 6,569,603 (Furukawa et al.), and 6,893,797 (Munnelly et al.), all of which are incorporated herein by reference. Also useful are the vinyl carbazole polymers described in U.S. Pat. No. 7,175,949 (Tao et al.), and the polymers having pendant vinyl groups as described in U.S. Pat. No. 7,279,255 (Tao et al.), both patents being incorporated herein by reference. Useful are random copolymers derived from polyethylene glycol methacrylate/acrylonitrile/styrene monomers in random fashion and in particulate form, dissolved random copolymers derived from carboxyphenyl methacrylamide/acrylonitrile/-methacrylamide/N-phenyl maleimide, random copolymers derived from polyethylene glycol methacrylate/acrylonitrile/vinyl carbazole/styrene/-methacrylic acid, random copolymers derived from N-phenyl maleimide/methacrylamide/methacrylic acid, random copolymers derived from urethane-acrylic intermediate A (the reaction product of p-toluene sulfonyl isocyanate and hydroxylethyl methacrylate)/acrylonitrile/N-phenyl maleimide, and random copolymers derived from N-methoxymethyl methacrylamide/methacrylic acid/acrylonitrile/n-phenylmaleimide. By “random” copolymers, we mean the conventional use of the term, that is, the structural units in the polymer backbone that are derived from the monomers are arranged in random order as opposed to being block copolymers, although two or more of the same structural units can be in a chain incidentally.

For those lithographic printing plate precursors of this invention that are designed for off-press development using an aqueous alkaline developer or organic solvent-containing developer, the primary polymeric binders can be selected from any alkaline solution soluble (or dispersible) polymer having an acid value of from about 20 to about 400 (typically from about 30 to about 200). The following described polymeric binders are particularly useful in the manner but this is not an exhaustive list:

I. Polymers formed by polymerization of a combination or mixture of (a) (meth)acrylonitrile, (b) poly(alkylene oxide) esters of (meth)acrylic acid, and optionally (c) (meth)acrylic acid, (meth)acrylate esters, styrene and its derivatives, and (meth)acrylamide as described for example in U.S. Pat. No. 7,326,521 (Tao et al.) that is incorporated herein by reference. Some particularly useful polymeric binders in this class are derived from one or more (meth)acrylic acids, (meth)acrylate esters, styrene and its derivatives, vinyl carbazoles, and poly(alkylene oxide) (meth)acrylates.

II. Polymers having pendant allyl ester groups as described in U.S. Pat. No. 7,332,253 (Tao et al.) that is incorporated herein by reference. Such polymers can also include pendant cyano groups or have recurring units derived from a variety of other monomers as described in Col. 8, line 31 to Col. 10, line 3 of the noted patent.

III. Polymers having all carbon backbones wherein at least 40 and up to 100 mol % (and typically from about 40 to about 50 mol %) of the carbon atoms forming the all carbon backbones are tertiary carbon atoms, and the remaining carbon atoms in the all carbon backbone being non-tertiary carbon atoms. By “tertiary carbon”, we refer to a carbon atom in the all carbon backbone that has three valences filled with radicals or atoms other than a hydrogen atom (which fills the fourth valence). By “non-tertiary carbon”, we mean a carbon atom in the all carbon backbone that is a secondary carbon (having two valences filled with hydrogen atoms) or a quaternary carbon (having no hydrogen atoms attached). Typically, most of the non-tertiary carbon atoms are secondary carbon atoms. One way to represent a tertiary carbon atom in the all carbon backbone is with the following Structure (T-CARBON):

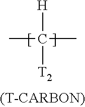

wherein T₂ is a group other than hydrogen provided that T₂ does not include an ethylenically unsaturated free radically reactive group (such as a —C═C— group). In many embodiments, T₂ is a pendant group selected from N-carbazole, aryl (defined similarly as for Ar below), halo, cyano, —C(═O)R, —C(═O)Ar, —C(═O)OR, —C(═O)OAr, —C(═O)NHR, and —C(═O)NHAr pendant groups, wherein R is hydrogen or an alkyl, cycloalkyl, halo, alkoxy, acyl, or acyloxy group, and Ar is an aryl group other than a styryl group. The quaternary carbon atoms present in the all carbon backbone of the polymeric binder can also have the same or different pendant groups filling two of the valences. For example, one or both valences can be filled with the same or different alkyl groups as defined above for R, or one valence can be filled with an alkyl group and another valence can be filled with a N-carbazole, aryl other than a styryl group, halo, cyano, —C(═O)R, —C(═O)Ar, —C(═O)OR, —C(═O)OAr, —C(═O)NHR, or —C(═O)NHAr pendant group, wherein R and Ar are as defined above. The pendant groups attached to the tertiary and quaternary carbons in the all carbon backbone can be the same or different and typically, they are different. It should also be understood that the pendant groups attached to the various tertiary carbon atoms can be the same throughout the polymeric molecule, or they can be different. For example, the tertiary carbon atoms can be derived from the same or different ethylenically unsaturated polymerizable monomers. Moreover, the quaternary carbon atoms throughout the polymeric molecule can have the same or different pendant groups.

In some embodiments of this invention, the polymeric binder can be represented by the following Structure:

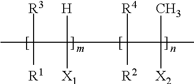

that is defined in more details in U.S. Patent Application Publication 2008-0280229 (Tao et al.) that is incorporated herein by reference.

Representative recurring units comprising tertiary carbon atoms can be derived from one or more ethylenically unsaturated polymerizable monomers selected from vinyl carbazole, styrene and derivatives thereof (other than divinylbenzene and similar monomers that provide pendant carbon-carbon polymerizable groups), acrylic acid, acrylonitrile, acrylamides, acrylates, and methyl vinyl ketone. As noted above, two or more different recurring units can be used. Similarly, representative recurring units with secondary or quaternary carbon atoms can be derived from one or more ethylenically unsaturated polymerizable monomers selected from methacrylic acid, methacrylates, methacrylamides, and α-methylstyrene.

IV. Polymeric binders that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups can be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. Nos. 4,874,686 (Urabe et al.), 7,729,255 (Tao et al.), 6,916,595 (Fujimaki et al.), and 7,041,416 (Wakata et al.) that are incorporated by reference, especially with respect to the general formulae (1) through (3) noted in EP 1,182,033A1.

V. Polymeric binders can have pendant 1H-tetrazole groups as described in U.S. Patent Application Publication 2009-0142695 (Baumann et al.) that is incorporated herein by reference.

VI. Still other useful polymeric binders can be homogenous, that is, dissolved in the coating solvent, or can exist as discrete particles and include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (noted above) and U.S. Pat. Nos. 6,309,792 (Hauck et al.), 6,352,812 (Shimazu et al.), 6,569,603 (noted above), and 6,893,797 (Munnelly et al.). Also useful are the vinyl carbazole polymers described in U.S. Pat. No. 7,175,949 (Tao et al.). Other useful polymeric binders are particulate poly(urethane-acrylic) hybrids that are distributed (usually uniformly) throughout the imageable layer. Each of these hybrids has a molecular weight of from about 50,000 to about 500,000 and the particles have an average particle size of from about 10 to about 10,000 nm (typically from about 30 to about 500 nm).

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B.M. Monroe in Radiation Curing: Science and Technology, S. P. Pappas, Ed., Plenum, N.Y., 1992, pp. 399-440, and in “Polymer Imaging” by A. B. Cohen and P. Walker, in Imaging Processes and Material, J. M. Sturge et al. (Eds.), Van Nostrand Reinhold, N.Y., 1989, pp. 226-262. For example, useful free radically polymerizable components are also described in EP 1,182,033A1 (Fujimaki et al.), beginning with paragraph [0170], and in U.S. Pat. Nos. 6,309,792 (Hauck et al.), 6,569,603 (Furukawa), and 6,893,797 (Munnelly et al.). Other useful free radically polymerizable components include those described in U.S. Patent Application Publication 2009/0142695 (Baumann et al.), which radically polymerizable components include 1H-tetrazole groups.

In addition to, or in place of the free radically polymerizable components described above, the radiation-sensitive composition can include polymeric materials that include side chains attached to the backbone, which side chains include one or more free radically polymerizable groups (such as ethylenically unsaturated groups) that can be polymerized (crosslinked) in response to free radicals produced by the initiator composition (described below). There can be at least two of these side chains per molecule. The free radically polymerizable groups (or ethylenically unsaturated groups) can be part of aliphatic or aromatic acrylate side chains attached to the polymeric backbone. Generally, there are at least 2 and up to and including 20 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

This radiation-sensitive composition also includes an initiator composition that includes one or more initiators that are capable of generating free radicals sufficient to initiate polymerization of all the various free radically polymerizable components upon exposure of the composition to imaging infrared radiation. The initiator composition is responsive, for example, to electromagnetic radiation in the infrared spectral regions, corresponding to the broad spectral range of at least 700 nm and up to and including 1400 nm, and typically radiation of at least 700 nm and up to and including 1250 nm.

More typically, the initiator composition includes one or more an electron acceptors and one or more co-initiators that are capable of donating electrons, hydrogen atoms, or a hydrocarbon radical.

In general, suitable initiator compositions for IR-radiation sensitive compositions comprise initiators that include but are not limited to, aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts).

Useful initiator compositions for IR radiation sensitive compositions include onium compounds including ammonium, sulfonium, iodonium, and phosphonium compounds. Useful iodonium cations are well known in the art including but not limited to, U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), and 6,051,366 (Baumann et al.). For example, a useful iodonium cation includes a positively charged iodonium, (4-methylphenyl)[4-(2-methylpropyl)phenyl]-moiety and a suitable negatively charged counterion.

Thus, the iodonium cations can be supplied as part of one or more iodonium salts, and the iodonium cations can be supplied as iodonium borates also containing suitable boron-containing anions. For example, the iodonium cations and the boron-containing anions (such as tetraarylborate anions) can be supplied as part of substituted or unsubstituted diaryliodonium salts that are combinations of Structures (I) and (II) described in Cols. 6-8 of U.S. Pat. No. 7,524,614 (Tao et al.) that is incorporated herein by reference.

Useful IR radiation-sensitive initiator compositions can comprise one or more diaryliodonium borate compounds. Representative iodonium borate compounds useful in this invention include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexyl-phenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]borate, 4-methoxyphenyl-4′-cyclohexyl-phenyliodonium tetrakis(penta-fluorophenyl)borate, 4-methylphenyl-4′-dodecylphenyliodonium tetrakis(4-fluorophenyl)borate, bis(dodecylphenyl)-iodonium tetrakis(pentafluorophenyl)-borate, and bis(4-t-butylphenyl)iodonium tetrakis(1-imidazolyl)borate. Useful compounds include bis(4-t-butylphenyl)-iodonium tetraphenylborate, 4-methylphenyl-4′-hexylphenyliodonium tetraphenylborate, 2-methyl-4-t-butylphenyl-4′-methylphenyliodonium tetraphenylborate, and 4-methylphenyl-4′-cyclohexylphenyliodonium tetraphenylborate. Mixtures of two or more of these compounds can also be used in the initiator composition.

Thus, particularly useful initiator compositions include those having either an iodonium cation, a tetraaryl borate anion (such as a tetraphenyl borate anion), or a salt having an iodonium cation and tetraaryl borate anion.

The imageable layers comprise a radiation-sensitive imaging composition that includes one or more infrared radiation absorbing compounds, such as first and second infrared radiation absorbing compounds. If only a single infrared radiation absorbing compound is present, it can be any of the compounds described below. The total amount of one or more infrared radiation absorbing compounds is at least 2 and up to and including 30 weight %, or typically at least 5 and up to and including 20 weight %, based on the imageable layer total solids.

In some embodiments, there is a mixture of such compounds and the first infrared radiation absorbing compounds are sensitive to both infrared radiation (typically of at least 700 and up to and including 1400 nm) and visible radiation (typically of at least 450 and up to and including 700 nm). These compounds also have a tetraaryl pentadiene chromophore. Such chromophore generally includes a pentadiene linking group having 5 carbon atoms in the chain, to which are attached two substituted or unsubstituted aryl groups at each end of the linking group. These aryl groups can be substituted with the same or different tertiary amine groups. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain. For example, useful first infrared radiation absorbing compounds can be represented by the following Structure (DYE-I)

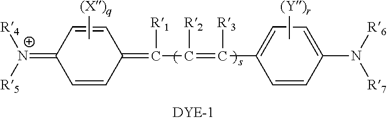

wherein R₁′, R₂′, and R₃′ each independently represents hydrogen, or a halo, cyano, alkoxy, aryloxy, acyloxy, carbamoyl, acyl, acylamido, alkylamino, arylamino, alkyl, aryl, or heteroaryl group, or any two of R₁′, R₂′, and R₃′ groups can be joined together or with an adjacent aromatic ring to complete a 5- to 7-membered carbocylic or heterocyclic ring,

R₄′, R₅′, R₆′, and R₇′ each independently represents hydrogen, an alkyl group having 1 to 8 carbon atoms, a cycloalkyl group having 4 to 6 carbon atoms in the ring, an aryl group having 6 to 10 carbon atoms in the ring, or a heteroaryl group having 5 to 10 carbon and heteroatoms in the ring, or R₄′ and R₅′ or R₆′ and R₇′ can be joined together to form a 5- to 9-membered heterocyclic ring, or R₄′, R₅′, R₆′, or R₇′ can be joined to a carbon atom of an adjacent aromatic ring at a position ortho to the position of attachment of the anilino nitrogen to form, along with the nitrogen to which they are attached, a 5- or 6-membered heterocyclic ring,

s is 2,

Z₂ is a monovalent anion,

X″ and Y″ are independently R₁′ or the atoms necessary to complete a 5- to 7-membered fused carbocyclic or heterocyclic ring, and

q and r are independently integers of from 1 to 4.

In Structure (DYE-I), Z₂⁻ is a suitable counterion that can be derived from a strong acid, and include such anions as ClO₄⁻, BF₄⁻, CF₃SO₃⁻, PF₆⁻, AsF₆⁻, SbF₆⁻, and perfluoroethylcyclohexylsulfonate. Other cations include boron-containing anions as described above (borates), methylbenzenesulfonic acid, benzenesulfonic acid, methanesulfonic acid, p-hydroxybenzenesulfonic acid, p-chlorobenzenesulfonic acid, tosylate, and halides. Particularly useful counterions are alkyltriphenyl borate anions.

In some embodiments, the first infrared radiation absorbing compound is represented by the following Structure (DYE-II) or (DYE-III):

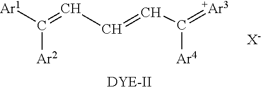

wherein Ar¹ through Ar⁴ are the same or different aryl groups wherein at least one and up to three of the aryl groups are substituted with a tertiary amino group, and X⁻ is a counterion (as described above for Z₂⁻),

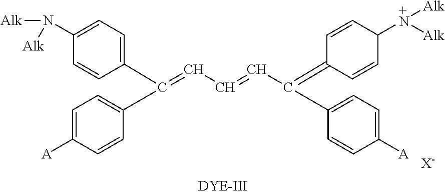

wherein Alk represents the same or different alkyl groups having 1 to 7 carbon atoms, A represents hydrogen or the same or different substituted or unsubstituted lower alkyl group having 1 to 3 carbon atoms or the same or different dialkylamino groups, and X⁻ is a counterion (as described above for Z₂⁻).

Examples of useful first infrared radiation absorbing compounds include the following compounds that can also be used in a mixture:

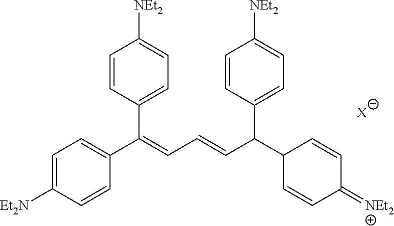

X⁻ is tosylate or an alkyltriphenylborate.

The first infrared radiation absorbing compound is generally present in an amount of up to and including 2 weight %, or at least 0.2 and up to and including 2 weight %, or more typically at least 0.4 and up to and including 1.5, all based on the total solids of the imageable layer.

When a mixture of compounds is present, the amount of the first infrared radiation absorbing compound in the imageable layer can be less than the amount of the second infrared radiation absorbing compound. For example, the molar ratio of the first infrared radiation absorbing compound to the second infrared radiation absorbing compound (described below) is at least 1:1.5 and up to and including 1:6, or more likely at least 1:2 and up to and including 1:4.

In mixtures of infrared radiation absorbing compounds, the second infrared radiation (IR) absorbing compound can be any known IR absorbing compound as long as it is different than the first infrared radiation absorbing compound. The second infrared radiation absorbing compounds are to infrared radiation (typically of at least 700 and up to and including 1400 nm) but are not particularly sensitive to visible radiation (typically of at least 450 and up to and including 700 nm). For example, useful second IR absorbing compounds can include various IR-sensitive dyes (“IR dyes”). Examples of suitable second IR dyes include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. Nos. 5,208,135 (Patel et al.), 6,153,356 (Urano et al.), 6,264,920 (Achilefu et al.), 6,309,792 (Hauck et al.), 6,569,603 (noted above), 6,787,281 (Tao et al.), 7,135,271 (Kawaushi et al.), and EP 1,182,033A2 (noted above). Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.).

In addition to low molecular weight IR-absorbing dyes having IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (noted above), 6,264,920 (Achilefu et al.), 6,153,356 (noted above), and 5,496,903 (Watanabe et al.). Suitable dyes can be formed using conventional methods and starting materials or obtained from various commercial sources including American Dye Source (Baie D'Urfe, Quebec, Canada) and FEW Chemicals (Germany). Other useful dyes for near infrared diode laser beams are described in U.S. Pat. No. 4,973,572 (DeBoer).

Useful IR-radiation sensitive compositions are described, for example, in the following patent and published patent applications:

U.S. Pat. No. 7,452,638 (Yu et al.),

U.S. Patent Application Publication 2008/0254387 (Yu et al.),

U.S. Patent Application Publication 2008/0311520 (Yu et al.),

U.S. Patent Application Publication 2009/0263746 (Ray et al.), and

U.S. Patent Application Publication 2010/0021844 (Yu et al.).

In a mixture of infrared radiation absorbing compounds, the second infrared radiation absorbing compounds can be present in the radiation sensitive composition (or imageable layer) in an amount generally of at least 0.5% and up to and including 10% and typically at least 1% and up to and including 6%, based on dry weight of the imageable layer.

Besides any organic polymeric binder that can have pendant phosphoric acid groups, the imageable layer composition used in this invention also includes one or more inorganic phosphoric acid (or inorganic phosphoric acid precursor) in an amount of at least 0.1 and up to and including 4 weight %, and typically at least 0.3 and up to and including 3 weight %, based on the imageable layer total solids. By the term “phosphoric acid”, we meant to include what is known as orthophosphoric acid (H₃PO₄) as well as inorganic polyphosphoric acids having the formula HO—(PO₂OH)ₓH wherein x is the number of phosphoric acid units in the molecule. Such compounds can be a phosphoric acid precursor that forms orthophosphoric acid upon hydrolysis. Other useful phosphoric acid precursors include pyrophosphoric acid, metaphosphoric acid, and phosphoric anhydride.

The imageable layer can also include a “primary additive” that is a poly(alkylene glycol) or an ether or ester thereof that has a molecular weight of at least 200 and up to and including 4000. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate.

The imageable layer can further include a “secondary additive” that is a poly(vinyl alcohol), a poly(vinyl pyrrolidone), poly(vinyl imidazole), or polyester in an amount of up to and including 20 weight % based on the total dry weight of the imageable layer.

Additional additives to the imageable layer include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Inno et al.). The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts.

The radiation-sensitive composition and imageable layer optionally includes a phosphate (meth)acrylate having a molecular weight generally greater than 250 as described in U.S. Pat. No. 7,429,445 (Munnelly et al.) that is incorporated herein by reference. By “phosphate (meth)acrylate” we also mean “phosphate methacrylates” and other derivatives having substituents on the vinyl group in the acrylate moiety.

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imageable layer.

In most embodiments, such as the on-press developable lithographic printing plate precursors, the imageable layer is the outermost layer. However, in off-press developable lithographic printing plate precursors, the outermost layer can be a water-soluble or water-dispersible overcoat (also sometimes known as an “oxygen impermeable topcoat” or “oxygen barrier layer”) disposed over the imageable layer. Such overcoat layers can comprise one or more water-soluble poly(vinyl alcohol)s having a saponification degree of at least 90% and generally have a dry coating weight of at least 0.1 and up to and including 2 g/m² in which the water-soluble poly(vinyl alcohol)s comprise at least 60% and up to and including 99% of the dry overcoat layer weight.

The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a random copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), and random copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.) that is incorporated by reference.

Illustrative of such manufacturing methods is mixing the various components needed for a specific imaging chemistry in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Invention Examples below. After proper drying, the coating weight of the imageable layer is generally at least 0.1 and up to and including 5 g/m² or at least 0.5 and up to and including 3.5 g/m².

Layers can also be present under the imageable layer to enhance developability or to act as a thermal insulating layer.

Once the various layers have been applied and dried on the substrate, the negative-working imageable elements can be enclosed in water-impermeable material that substantially inhibits the transfer of moisture to and from the element and “heat conditioned” as described in U.S. Pat. No. 7,175,969 (noted above) that is incorporated herein by reference.

The lithographic printing plate precursors can be stored and transported as stacks of precursors within suitable packaging and containers known in the art.

### Imaging Conditions

During use, the lithographic printing plate is exposed to a suitable source of exposing radiation depending upon the second infrared radiation absorbing compound present in the radiation-sensitive composition to provide specific sensitivity that is at a wavelength of at least 700 and up to and including 1400 nm, or at least 750 and up to and including 1250 nm.

For example, imaging can be carried out using imaging or exposing radiation from an infrared laser (or array of lasers) at a wavelength of at least 750 nm and up to and including about 1400 nm and typically at least 750 nm and up to and including 1250 nm. Imaging can be carried out using imaging radiation at multiple wavelengths at the same time if desired.

The laser used to expose the lithographic printing plate precursor is usually a diode laser, because of the reliability and low maintenance of diode laser systems, but other lasers such as gas or solid-state lasers can also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can be configured as a flatbed recorder or as a drum recorder, with the lithographic printing plate precursor mounted to the interior or exterior cylindrical surface of the drum. An example of an useful imaging apparatus is available as models of Kodak® Trendsetter platesetters available from Eastman Kodak Company that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.).

Imaging with infrared radiation can be carried out generally at imaging energies of at least 30 mJ/cm² and up to and including 500 mJ/cm², and typically at least 50 and up to and including 300 mJ/cm² depending upon the sensitivity of the imageable layer.

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

For off-press developed precursors, after imaging, a heating step (pre-heating) might be used to accelerate the formation of a latent image. This heating step can be realized in so called “preheat units” that can be a separate machine or integrated into the processor (for off-press development) that develops the imaged precursor. There are different types of preheat units. The most common ones use infrared radiation or hot air circulation, or combination thereof, to heat the imaged element. The temperature used for the purpose is at least 70 and up to and including 200° C. However, it can be advantageous to omit the preheating step to simplify the process for making lithographic printing plates.

A pre-rinse step might be carried out in a stand-alone apparatus or by manually rinsing the imaged precursor with water or the pre-rinse step can be carried out in a washing unit that is integrated in a processor used for developing the imaged precursor.

### Development and Printing

After thermal imaging, some embodiments of imaged precursors are processed (developed) “off-press” using a single aqueous processing solution that can be an aqueous alkaline processing solution having a pH of at least 9 and up to and including 13.5, or typically at least 9.5 and up to and including 12, or even from 10 to 12. Processing is carried out for a time sufficient to remove predominantly only the non-exposed regions of the imaged imageable layer to reveal the hydrophilic surface of the substrate, but not long enough to remove significant amounts of the exposed regions. The revealed hydrophilic surface repels inks while the exposed regions containing polymerized or crosslinked polymer accept ink. Thus, the non-exposed regions to be removed are “soluble” or “removable” in the aqueous alkaline solution because they are removed, dissolved, or dispersed within it more readily than the regions that are to remain. The term “soluble” also means “dispersible”.

Development can be accomplished using what is known as “manual” development, “dip” development, or processing with an automatic development apparatus (processor). In the case of “manual” development, development is conducted by rubbing the entire imaged precursor with a sponge or cotton pad sufficiently impregnated with a processing solution (described below), and optionally followed by rinsing with water. “Dip” development involves dipping the imaged precursor in a tank or tray containing the appropriate aqueous alkaline solution for at least 10 and up to and including 60 seconds under agitation, optionally followed by rinsing with water with or without rubbing with a sponge or cotton pad. The use of automatic development apparatus is well known and generally includes pumping an aqueous alkaline solution into a developing tank or ejecting it from spray nozzles. The apparatus can also include a suitable rubbing mechanism (for example a brush or roller) and a suitable number of conveyance rollers. Some developing apparatus include laser exposure means and the apparatus is divided into an imaging section and a developing section.

Developers or processing solutions commonly include surfactants, chelating agents (such as salts of ethylenediaminetetraacetic acid), organic solvents (such as benzyl alcohol), and alkaline components (such as inorganic metasilicates, organic metasilicates, hydroxides, and bicarbonates). The pH of the developer is generally greater than 7 and up to and including 14. Both aqueous alkaline developers and organic solvent-containing developers can be used.

Useful alkaline aqueous developers include 3000 Developer, 9000 Developer, GOLDSTAR Developer, GREENSTAR Developer, ThermalPro Developer, PROTHERM Developer, MX1813 Developer, and MX1710 Developer (all available from Eastman Kodak Company).

Organic solvent-containing developers are generally single-phase processing solutions of one or more organic solvents that are miscible with water.

Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. The organic solvent(s) is generally present in an amount of from about 0.5 and up to 15% based on total developer weight. The organic solvent-containing developers can be neutral, alkaline, or slightly acidic in pH, and preferably, they are alkaline in pH.

Representative solvent-containing developers include ND-1 Developer, Developer 980, Developer 1080, 2 in 1 Developer, 955 Developer, D29 Developer (described below), and 956 Developer (all available from Eastman Kodak Company). These developers can be diluted with water if desired.

In some instances, a single aqueous processing solution can be used to both develop the imaged precursor by removing predominantly the non-exposed regions and also to provide a protective layer or coating over the entire imaged and developed surface. In this aspect, the aqueous alkaline solution behaves somewhat like a gum that is capable of protecting (or “gumming”) the lithographic image on the printing plate against contamination or damage (for example, from oxidation, fingerprints, dust, or scratches). The aqueous alkaline solution generally includes an organic amine having a boiling point of less than 300° C. (and typically of at least 50°), a film-forming hydrophilic polymer, and optionally an anionic or nonionic surfactant. The pH of the aqueous alkaline solution can be adjusted by adding a suitable amount of a alkaline component such as alkali silicates (including metasilicates), alkali metal hydroxides (such as sodium hydroxide and potassium hydroxide), and quaternary ammonium hydroxides. Tap water can be used to make up the solution and generally provides from 45 to 98 weight % of the solution.

Useful organic amines are relatively volatile organic primary, secondary, and tertiary amines that include but are not limited to, alkanolamines (including cycloalkyl amines), carbocyclic aromatic amines, and heterocyclic amines, that are present in a total amount of at least 0.1 weight % and generally up to and including 50 weight %. Useful amines are mono-, di- and trialkanol amines such as monoethanolamine, diethanolamine, triethanolamine, and mono-n-propanolamine, or combinations of these compounds.

One or more film-forming water-soluble or hydrophilic polymers are present in the aqueous alkaline solution in an amount of at least 0.25 weight % and up to 30 weight % and typically at least 1 and up to and including 15 weight %. Examples of useful polymers of this type include but are not limited to, gum arabic, pullulan, cellulose derivatives (such as hydroxymethyl celluloses, carboxymethylcelluloses, carboxyethylcelluloses, and methyl celluloses), starch derivatives [such as (cyclo)dextrins, starch esters, dextrins, carboxymethyl starch, and acetylated starch] poly(vinyl alcohol), poly(vinyl pyrrolidone), polyhydroxy compounds [such as polysaccharides, sugar alcohols such as sorbitol, miso-inosit, homo- and copolymers of (meth)acrylic acid or (meth)acrylamide], copolymers of vinyl methyl ether and maleic anhydride, copolymers of vinyl acetate and maleic anhydride, copolymers of styrene and maleic anhydride, and copolymers having recurring units with carboxy, sulfo, or phospho groups, or salts thereof. Useful hydrophilic polymers include gum arabic, (cyclo)dextrin, a polysaccharide, a sugar alcohol, or a homo- or copolymer having recurring units derived from (meth)acrylic acid.

The aqueous alkaline solution optionally includes one or more anionic, amphoteric, or nonionic surfactants (or both) in an amount of at least 0.25 and up to and including 50 weight %, and typically at least 0.25 and up to and including 30 weight %.

Additional optional components of the aqueous alkaline solutions used in this invention include antifoaming agents, buffers, biocides, complexing agents, and small amounts of water-miscible organic solvents such as reaction products of phenol with ethylene oxide and propylene oxide, benzyl alcohol, esters of ethylene glycol and propylene glycol with acids having 6 or less carbon atoms, sludge inhibitors (such as filter dyes and free-radical inhibitors), odorants, anti-corrosion agents, and dyes.

Following processing, the resulting lithographic printing plate can be used for printing with or without a separate rinsing step using water.

The resulting lithographic printing plate can also be baked in a postbake operation can be carried out, with or without a blanket or floodwise exposure to UV or visible radiation using known conditions. Alternatively, a blanket UV or visible radiation exposure can be carried out, without a postbake operation.

Printing can be carried out by applying a lithographic printing ink and fountain solution to the printing surface of the imaged and developed precursor. The fountain solution is taken up by the non-imaged regions, that is, the surface of the hydrophilic substrate revealed by the imaging and processing steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material.

In other embodiments, the imaged lithographic printing plate precursors are developed “on-press”. A post-exposure baking step can be omitted. The imaged precursor is mounted on press wherein the unexposed regions in the imageable layer are removed by a suitable fountain solution, lithographic printing ink, or a combination of both, when the initial printed impressions are made. Typical ingredients of aqueous fountain solutions include pH buffers, desensitizing agents, surfactants and wetting agents, humectants, low boiling solvents, biocides, antifoaming agents, and sequestering agents. A representative example of a fountain solution is Varn Litho Etch 142W+Varn PAR (alcohol sub) (available from Varn International, Addison, Ill.).

The fountain solution is taken up by the non-imaged regions, that is, the surface of the hydrophilic substrate revealed by the imaging and development steps, and ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged precursor to the receiving material. The imaged precursors can be cleaned between impressions, if desired, using conventional cleaning means.

The present invention provides at least the following embodiments and combinations thereof, but other combinations of features are considered to be within the present invention as a skilled artisan would appreciate from the teaching of this disclosure:

1. A negative-working, infrared radiation-sensitive lithographic printing plate precursor comprising a substrate and having thereon an imageable layer comprising:

a free radically polymerizable component,

an initiator composition capable of generating free radicals upon exposure to infrared radiation,

a polymeric binder,

one or more infrared radiation absorbing compounds, and

an inorganic phosphoric acid or inorganic phosphoric acid precursor in an amount of at least 0.1 weight % of the imageable layer total solids.

2. The lithographic printing plate precursor of embodiment 1 wherein the inorganic phosphoric acid or inorganic phosphoric acid precursor is present in the imageable layer in an amount of at least 0.1 and up to and including 4 weight % of the imageable layer total solids.

3. The lithographic printing plate precursor of embodiment 1 or 2 comprising two different infrared radiation absorbing compounds wherein a first infrared radiation absorbing compound is present in an amount of up to 2 weight %, and a second infrared radiation absorbing compound that is present in an amount of at least 0.5 and up to and including 10 weight %, based on the total solids of the imageable layer.

4. The lithographic printing plate precursor of any of embodiments 1 to 3 that is on-press developable.

5. The lithographic printing plate precursor of any of embodiments 1 to 4 wherein the polymeric binder comprises a polymer backbone to which are directly or indirectly linked poly(alkylene glycol) side chains.

6. The lithographic printing plate precursor of any of embodiments 1 to 5 wherein the polymeric binder has a polymer backbone to which are attached both poly(alkylene glycol) side chains that contain at least 10 alkylene glycol units, and cyano side chains.

7. The lithographic printing plate precursor of embodiment 4 or 5 wherein the polymeric binder is present at least partially as discrete particles.

8. The lithographic printing plate precursor of any of embodiments 1 to 7 wherein the initiator composition comprises an electron acceptor and a co-initiator that is capable of donating electrons, hydrogen atoms, or a hydrocarbon radical.

9. The lithographic printing plate precursor of any of embodiments 1 to 8 wherein the first infrared radiation absorbing compound is an infrared radiation absorbing dye that effectively absorbs infrared radiation at a wavelength of at least 700 and up to and including 1400 nm.

10. The lithographic printing plate precursor of any of embodiments 1 to 9 wherein the substrate is a sulfuric acid-anodized aluminum substrate.

11. The lithographic printing plate precursor of embodiment 10 wherein the sulfuric acid-anodized aluminum substrate has been post-treated with a hydrophilic interlayer prior to applying the imageable layer.

12. The lithographic printing plate precursor of any of embodiments 1 to 11 that is on-press developable, the substrate is a sulfuric acid-anodized aluminum substrate, the imageable layer comprises, and the inorganic phosphoric acid or inorganic phosphoric acid precursor is present in the imageable layer in an amount of at least 0.1 and up to and including 4 weight % of the imageable layer total solids.

13. The lithographic printing plate precursor of any of embodiments 1 to 12 wherein the initiator composition comprises either an iodonium cation, a tetraarylborate anion, or a salt having an iodonium cation and a tetraarylborate anion.

14. A method of making a lithographic printing plate comprising:

A) imagewise exposing the negative-working, infrared radiation-sensitive lithographic printing plate precursor of any of embodiments 1 to 13 to imaging infrared radiation to produce exposed and non-exposed regions in the imageable layer, and

B) developing the imagewise exposed precursor to remove the non-exposed regions of the imageable layer.

15. The method of embodiment 14 wherein developing is carried out on-press using a fountain solution, lithographic printing ink, or a combination thereof

16. The method of embodiment 14 or 15 wherein the imageable layer of the lithographic printing plate precursor contains a polymeric binder that comprises a polymer backbone to which are directly or indirectly linked poly(alkylene glycol) side chains.

17. The method of embodiment 14 wherein developing is carried out off-press using an aqueous processing solution.

18. The method of any of embodiments 14 to 17 wherein the imageable layer of the lithographic printing plate precursor contains a polymeric binder that has a polymer backbone to which are attached both poly(alkylene glycol) side chains that contain at least 10 alkylene glycol units, and cyano side chains.

19. The method of any of embodiments 14 to 18 wherein the imageable layer of the lithographic printing plate precursor contains a polymeric binder that is present at least partially as discrete particles.

20. The method of any of embodiments 14 to 19 wherein the lithographic printing plate precursor is on-press developable having a substrate that is a sulfuric acid-anodized aluminum substrate, a imageable layer that comprises the inorganic phosphoric acid or inorganic phosphoric acid precursor that is present in the imageable layer in an amount of at least 0.1 and up to and including 4 weight % of the imageable layer total solids.

21. A lithographic printing plate obtained from the method of any of embodiments 14 to 20.

The following Examples are provided to illustrate the practice of this invention and are not meant to be limiting in any manner.

The components and materials used in the examples were as follows:

Byk® 336 surfactant was obtained from Byk Chemie (Wallingford, Conn.).
Copolymer A Latex polymer derived from poly(ethylene glycol) methacrylate:acrylonitrile:styrene at 10:70:20 (Binder-dispersion with 24% solids) in 80:20 propanol:water (Binder).
Klucel® M is a hydroxypropyl cellulose that was obtained from Hercules Inc. (Wilmington, Del.).
Elvacite® 4026 is a solid acrylic particulate resin.
IB05 is bis-(4-t-butylphenyl)iodonium tetraphenylborate.
S2024 is an IR Dye with the following structure that is available from FEW Chemicals Germany.

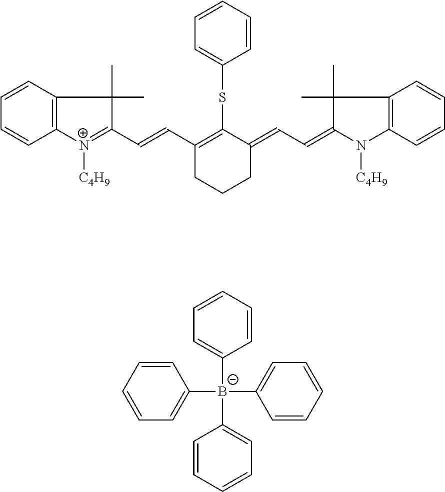

KAN 052545 has the following structure:

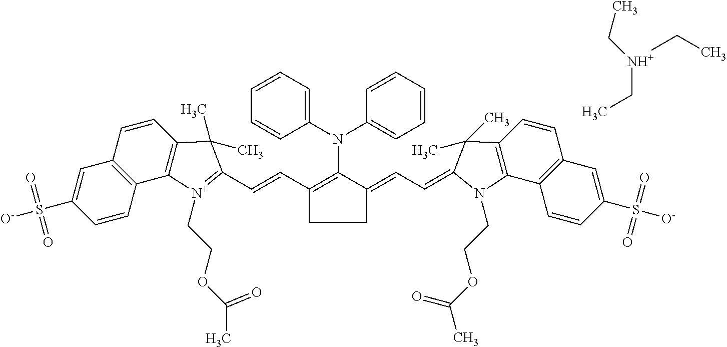

SR399 is dipentaerythritol pentaacrylate that is available from Sartomer.
Mercapto-3-triazole represents mercapto-3-triazole-1H,2,4 that was obtained from PCAS (Paris, France).
Oligomer A was a urethane acrylate prepared by reacting Desmodur® N100 (an aliphatic polyisocyanate resin based on hexamethylene diisocyanate from Bayer Corp., Milford, Conn.) with hydroxyethyl acrylate and pentaerythritol triacrylate (80 wt. % in 2-butanone).
MEK represents methyl ethyl ketone.
Dowanol® PM is propylene glycol methyl ether that can be obtained from Dow Chemical Company. It is also known in the art as PGME.
BLO represents γ-butyrolactone.
Blue 63 is a leuco dye that is available from Yamamoto Chemicals (Japan)
Pigment 951 is a 27% solids dispersion of 7.7 parts of a poly(vinyl acetal) derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4), and 15.4 parts of Disperbyk® 167 dispersant (Byk Chemie) in 1-methoxy-2-propanol.
Copolymer B is a random copolymer derived from carboxyphenyl-methacrylamide, acrylonitrile, methacrylamide, and N-phenyl maleimide in a weight ratio of 37/48/10/5.
Fluor N™ 2900 is a fluorosurfactant that was obtained from Cytonix Corporation (Beltsville, Md.).
NK Ester A-DPH is a dipentaerythritol hexaacrylate that was obtained from Kowa American (New York, N.Y.).
PVA405 is a poly(vinyl alcohol) with a hydrolysis degree of 80% that was obtained from Kuraray (Japan).

Substrate 1 is an electrochemically-grained and sulfuric acid-anodized aluminum support, with an oxide weight of 3.8 g/m² that had been post-treated with Solution A that is a 0.5 weight % solution containing poly(acrylic acid) (weight average molecular weight of about 5000), phosphoric acid, and Surfactant 10G nonionic surfactant in a weight ratio of 71.9:21.6:6.5. The post-treatment was done by first heating Solution A to 60° C. and then coating the heated Solution A using a bar coater to give a wet film of 21 g/m². After a dwell time of 10 seconds, the substrate was rinsed and dried for 2 minutes at 70° C.

Substrate 2 was obtained similarly to Substrate 1 except that Solution B was used, which was a 0.5 weight % of poly(vinyl phosphonic acid).

### Invention Examples 1-2 and Comparative Examples 1-2

Lithographic printing plate precursors were prepared by coating each of the imageable layer formulations shown in the following TABLE I (by parts) onto Substrate 1 using a bar coater and dried for 60 seconds at about 82° C. to provide a dry imageable layer coating weight of 1.0 g/m².

The precursors were exposed at 50 to 300 mJ/cm² using a Kodak® Trendsetter 3244x imagesetter at 7.2 W. To check the press properties, the imaged precursors shown in TABLE I were then directly mounted on a MAN Roland 04 press charged with Cora S 8900 Hartmann Black. The fountain solution was Sinal 5% in Wasser. The printing press was started and the damping system was engaged to wet the imaged precursors with fountain solution. After five revolutions, the inking system was engaged and again after 5 revolutions of ink, 200 copies were printed. The printed sheets were assessed for the number of sheets needed to print a clean background (DOP) and the number of sheets to get to full ink density (DOP-INK). The results are given below in TABLE I. To check the run length, printing was continued until image wear was observed. Good quality prints were obtained with all of the lithographic printing plates for up to 70,000 sheets.

To evaluate shelf life, the lithographic printing plate precursors were placed unpacked on a rack and subjected to simulated aging at 40° C./80% relative humidity (RH) for 5 days and allowed to equilibrate for 1 day. The precursors were then imaged as in Invention Examples 1-3 and the number of copies required to obtain clean sheets were again evaluated as above.

The results shown in TABLE I indicate that the precursors having phosphoric acid in the imageable layer had better DOP results, both in the fresh state and after the simulated aging test.

TABLE I

| | Example | | | |
|---|---|---|---|---|
| | | Invention | Com- | Invention |
| | Comparative 1 | 1 | parative 2 | 2 |
| n-Propanol | 10.1 | 10.1 | 10.1 | 10.1 |
| MEK | 4.1 | 4.1 | 4.1 | 4.1 |
| Dowanol ® PM | 8.5 | 8.5 | 8.5 | 8.5 |
| Water | 1.2 | 1.2 | 1.2 | 1.2 |
| BLO | 0.3 | 0.3 | 0.3 | 0.3 |
| Oligomer A | 0.828 | 0.828 | 0.828 | 0.828 |
| (40% in MEK) | | | | |
| SR399 | 0.838 | 0.838 | 0.838 | 0.838 |
| (40% in MEK) | | | | |
| Klucel M | 1.380 | 1.380 | 1.380 | 1.380 |
| (1% in water) | | | | |
| Elvacite^{(R)} 4026 | 0.690 | 0.690 | 0.690 | 0.690 |
| (10% in MEK) | | | | |
| IB05 | 0.069 | 0.069 | 0.069 | 0.069 |
| Mercapto-3-triazole | 0.014 | 0.014 | 0.014 | 0.014 |
| S2024 | 0.028 | 0.028 | 0.028 | 0.028 |
| Copolymer A | 1.742 | 1.742 | 1.742 | 1.742 |
| polymer latex | | | | |
| Phosphoric acid | 0 | 0.276 | 0 | 0.276 |
| (10% aqueous | | | | |
| solution) | | | | |
| Byk ® 336 (25% in | 0.125 | 0.125 | 0.125 | 0.125 |
| Dowanol ® PM) | | | | |
| Fresh DOP | 30 | 15 | 50 | 15 |
| DOP-INK | | | | |
| 5 Days at 40° C./ | 200 | 20 | 200 | 20 |
| 80% RH DOP | | | | |

### Invention Examples 3-5

Lithographic printing plate precursors of this invention were prepared by coating each of the imageable layer formulations shown in TABLE 2 (parts by weight) onto Substrate 2 as described above to provide a dry imageable layer coating weight of 1.0 g/m². The precursors were imaged as described in Invention Example 1 and the number of sheets required to give a clean background was noted for both the fresh precursors and those aged as described above for 5 days. The results shown in TABLE II indicate that the invention precursor containing phosphoric acid in the imageable layers exhibited improved DOP.

TABLE II

| | Invention Example | | |
|---|---|---|---|
| | 3 | 4 | 5 |
| n-Propanol | 10.132 | 10.132 | 10.132 |
| MEK | 4.078 | 4.078 | 4.078 |
| Dowanol ® PM | 8.492 | 8.492 | 8.492 |
| Water | 1.171 | 1.171 | 1.171 |
| BLO | 0.286 | 0.286 | 0.286 |
| Oligomer A (40% in MEK) | 0.845 | 0.845 | 0.845 |
| SR399 (40% in MEK) | 0.863 | 0.863 | 0.863 |
| Klucel M (1% in water) | 1.380 | 1.380 | 1.380 |
| Elvacite ® 4026 (10% in | 0.690 | 0.690 | 0.690 |
| MEK) | | | |
| IB05 | 0.069 | 0.069 | 0.069 |
| Mercapto-3-triazole | 0.038 | 0.038 | 0.038 |
| Blue 63 | 0.055 | 0.055 | 0.055 |
| KAN052545 | 0.055 | 0.055 | 0.055 |
| Copolymer A polymer latex | 1.772 | 1.772 | 1.772 |
| Phosphoric acid (10% | 0.069 | 1.38 | 0.276 |
| aqueous solution) | | | |
| Bye^{(R)} 336 (25% in | 0.125 | 0.125 | 0.125 |
| Dowanol^{(R)} PM) | | | |
| Fresh DOP | 1 | 1 | 1 |
| 5 Days at 40° C./80% RH | 600 | 200 | 2 |
| DOP | | | |

### Invention Example 6 and Comparative Example 3

Lithographic printing plate precursors were prepared by coating each of the imageable layer formulations shown in the following TABLE III (by parts) onto Substrate 2 using a bar coater and dried for 60 seconds at about 88° C. to provide a dry imageable layer coating weight of 1.5 g/m². On the resulting imageable layer, a topcoat formulation comprising 4 g of PVA405, 4 g of IPA, and 90 g of water, was applied to provide a dry topcoat coating weight of about 0.4 g/m². To check the shelf life of the lithographic printing plate precursors, samples of both precursors were packed with interleaf papers and wrapped with aluminum-lined wrapping paper and placed in a humidity oven set at 40° C. and 80% relative humidity for 10 days.

The fresh and aged precursors were exposed at 90 mJ/cm² using a Kodak® Trendsetter 3244x imagesetter at 7.2 W using a test pattern and processed at 23° C. off-press using a Mercury processor filled with 956 Developer (Eastman Kodak Company) at 120 mm/minute.

TABLE III

| | Comparative Example | |
|---|---|---|
| | 3 | Invention Example 6 |
| Copolymer B | 14.62 | 14.62 |
| Hybridur ® 580 | 19.50 | 19.50 |
| Phosmer PE | 4.43 | 4.43 |
| NK Ester A-DPH | 22.15 | 22.15 |
| SR399 | 22.15 | 22.15 |
| S2024 | 2.21 | 2.21 |
| IB05 | 7.97 | 7.97 |
| Pigment 951 (10%) | 6.09 | 6.09 |
| FluorN ™ 2900 | 0.89 | 0.89 |
| H₃PO₄ | 0 | 2.00 |
| Dowanol ® PM/PGME | 29.00 | 29.00 |
| Water | 10.00 | 10.00 |
| 1-Propanol | 6.60 | 6.60 |
| 4-Butyrolactone | 9.40 | 9.40 |
| BLO | 45.00 | 45.00 |

The resulting lithographic printing plates were mounted onto a Roland 200 Press that was charged with Offset S 7184 Ink abrasive ink with 10% Bologeneser Kreide (Sun Chemicals). The printing press was started with the dampening system made up of 4% Combifix XL 804 and 10% isopropyl alcohol. After a few revolutions, the inking system was engaged. Clean copies were obtained after only 3 printed sheets with both “fresh” lithographic printing plates from Comparative Example 3 and Invention Example 6, and with the “aged” lithographic printing plates from Invention Example 6 whereas the “aged” lithographic printing plates from Comparative Example 3 showed toning even after 1000 copies.

The invention has been described in detail with particular reference to certain preferred embodiments thereof, but it will be understood that variations and modifications can be effected within the spirit and scope of the invention.

1. A negative-working, infrared radiation-sensitive lithographic printing plate precursor comprising a substrate and having thereon an imageable layer comprising:
a free radically polymerizable component,
an initiator composition capable of generating free radicals upon exposure to infrared radiation,
a polymeric binder,
one or more infrared radiation absorbing compounds, and
an inorganic phosphoric acid or inorganic phosphoric acid precursor in an amount of at least 0.1 weight % of the imageable layer total solids.

2. The lithographic printing plate precursor of claim 1 wherein the inorganic phosphoric acid or inorganic phosphoric acid precursor is present in the imageable layer in an amount of at least 0.1 and up to and including 4 weight % of the imageable layer total solids.

3. The lithographic printing plate precursor of claim 1 comprising two different infrared radiation absorbing compounds wherein a first infrared radiation absorbing compound is present in an amount of up to 2 weight %, and a second infrared radiation absorbing compound that is present in an amount of at least 0.5 and up to and including 10 weight %, based on the total solids of the imageable layer.

4. The lithographic printing plate precursor of claim 1 that is on-press developable.

5. The lithographic printing plate precursor of claim 1 wherein the polymeric binder comprises a polymer backbone to which are directly or indirectly linked poly(alkylene glycol) side chains.

6. The lithographic printing plate precursor of claim 1 wherein the polymeric binder has a polymer backbone to which are attached both poly(alkylene glycol) side chains that contain at least 10 alkylene glycol units, and cyano side chains.

7. The lithographic printing plate precursor of claim 4 wherein the polymeric binder is present at least partially as discrete particles.

8. The lithographic printing plate precursor of claim 1 wherein the initiator composition comprises an electron acceptor and a co-initiator that is capable of donating electrons, hydrogen atoms, or a hydrocarbon radical.

9. The lithographic printing plate precursor of claim 1 wherein the first infrared radiation absorbing compound is an infrared radiation absorbing dye that effectively absorbs infrared radiation at a wavelength of at least 700 and up to and including 1400 nm.

10. The lithographic printing plate precursor of claim 1 wherein the substrate is a sulfuric acid-anodized aluminum substrate.

11. The lithographic printing plate precursor of claim 10 wherein the sulfuric acid-anodized aluminum substrate has been post-treated with a hydrophilic interlayer prior to applying the imageable layer.

12. The lithographic printing plate precursor of claim 1 that is on-press developable, the substrate is a sulfuric acid-anodized aluminum substrate, the imageable layer comprises, and the inorganic phosphoric acid or inorganic phosphoric acid precursor is present in the imageable layer in an amount of at least 0.1 and up to and including 4 weight % of the imageable layer total solids.

13. The lithographic printing plate precursor of claim 1 wherein the initiator composition comprises either an iodonium cation, a tetraarylborate anion, or a salt having an iodonium cation and a tetraarylborate anion.

14. A method of making a lithographic printing plate comprising:
A) imagewise exposing the negative-working, infrared radiation-sensitive lithographic printing plate precursor of claim 1 to imaging infrared radiation to produce exposed and non-exposed regions in the imageable layer, and
B) developing the imagewise exposed precursor to remove the non-exposed regions of the imageable layer.

15. The method of claim 14 wherein developing is carried out on-press using a fountain solution, lithographic printing ink, or a combination thereof.

16. The method of claim 15 wherein the imageable layer of the lithographic printing plate precursor contains a polymeric binder that comprises a polymer backbone to which are directly or indirectly linked poly(alkylene glycol) side chains.

17. The method of claim 14 wherein developing is carried out off-press using an aqueous processing solution.

18. The method of claim 14 wherein the imageable layer of the lithographic printing plate precursor contains a polymeric binder that has a polymer backbone to which are attached both poly(alkylene glycol) side chains that contain at least 10 alkylene glycol units, and cyano side chains.

19. The method of claim 14 wherein the imageable layer of the lithographic printing plate precursor contains a polymeric binder that is present at least partially as discrete particles.

20. The method of claim 14 wherein the lithographic printing plate precursor is on-press developable having a substrate that is a sulfuric acid-anodized aluminum substrate, a imageable layer that comprises the inorganic phosphoric acid or inorganic phosphoric acid precursor that is present in the imageable layer in an amount of at least 0.1 and up to and including 4 weight % of the imageable layer total solids.

21. A lithographic printing plate obtained from the method of claim 14.
